(19) United States
(12) Patent Application Publication
(10) Pub. No.: US 2008/0277910 A1
(43) Pub. Date: Nov. 13, 2008

(54) Vehicle seat including sensor

(75) Inventors: Gregory T. Thompson, Lawrenceville, GA (US); James G. Stanley, Novi, MI (US)

Correspondence Address: FOLEY AND LARDNER LLP;SUITE 500, 3000 K STREET NW, WASHINGTON, DC, 20007, US

(73) Assignee: TK Holdings Inc.

(21) Appl. No.: 12/149,925

(22) Filed: May 9, 2008

Related U.S. Application Data
(60) Provisional application No. 60/924,368, filed on May 10, 2007.

(51) Int. Cl. B60R 21/00; G01R 27/26

(52) U.S. Cl. 280/735; 324/663

(57) ABSTRACT

An occupation detection apparatus is provided including a conductor, a sensor, and a shielding electrode. The shielding electrode is located between the sensor and the conductor, and the shielding electrode is coupled, through a low impedance, to electrical ground. The conductor potentially represents an electrical potential of electrical ground. The coupling of the shielding electrode to electrical ground mitigates the susceptibility of the sensor to the conductor and other objects having a potential of electrical ground or near electrical ground.

### CROSS-REFERENCE TO RELATED PATENT APPLICATIONS

This application claims priority to and the benefit of U.S. Provisional Patent Application No. 60/924,368, filed on May 10, 2007 (incorporated by reference herein in its entirety).

### BACKGROUND

The present disclosure relates generally to the field of sensors. More specifically, the present disclosure relates to the use of shielding electrodes to shield electric field sensors from conductors and metal objects.

One application of electric field sensors is in a vehicle seat. An electric field sensor may be included in the seat. Without proper shielding, the sensor may be susceptible to the presence or absence of vehicle electrical grounds such as a grounded conductor or the seat frame. To prevent susceptibility of the sensor to such electrical grounds, a shielding electrode may be provided. One conventional method of providing a shielding electrode for a sensor discloses driving the shielding electrode with a signal substantially similar to a signal being driven through the sensor.

However, conventional systems that require the shielding electrode and the sensor to be driven by substantially the same signal introduce unwanted complexity. In particular, the signal required to drive both the shielding electrode and the sensor may change in amplitude or phase, with respect to one another, depending on the sensor sensory conditions. For example, in systems with a sensor designed to detect an object on a vehicle seat, the signal required to drive the shielding electrode may change in amplitude or phase relative to the sensor signal, depending on the load on the shield driving electronics. Such load variations could be caused by the seat being wet.

In light of the above, there is a need for an improved shielding device.

### SUMMARY

According to one disclosed embodiment, an occupant detection apparatus includes a sensor, and a shielding electrode. The shielding electrode is located between the sensor and a conductor and the shielding electrode is coupled, through a low impedance, to electrical ground.

According to another disclosed embodiment, a sensing system for a heated seat includes a heating element, a sensor, and a shielding electrode. The shielding electrode is located between the sensor and the heating element and the shielding electrode is coupled, through a low impedance, to electrical ground.

Another disclosed embodiment relates to an occupant classification system including a heating element, an electric field sensor, a shielding electrode and a controller. The shielding electrode is located between the sensor and the heating element and the shielding electrode is coupled, through a low impedance, to electrical ground. The controller is connected to the electric field sensor for classification of an occupant.

Another disclosed embodiment relates to a vehicle safety system including a heating element, an electric field sensor, a shielding electrode, and a controller. The shielding electrode is located between the sensor and the heating element and the shielding electrode is coupled, through a low impedance, to electrical ground. The controller is connected to the electric field sensor for controlling the vehicle safety system.

It is to be understood that both the foregoing general description and the following detailed description are exemplary and explanatory only, and are not restrictive of the invention as claimed. These and other features, aspects and advantages of the present invention will become apparent from the following description, appended claims, and the accompanying exemplary embodiments shown in the drawings, which are briefly described below.

### BRIEF DESCRIPTION

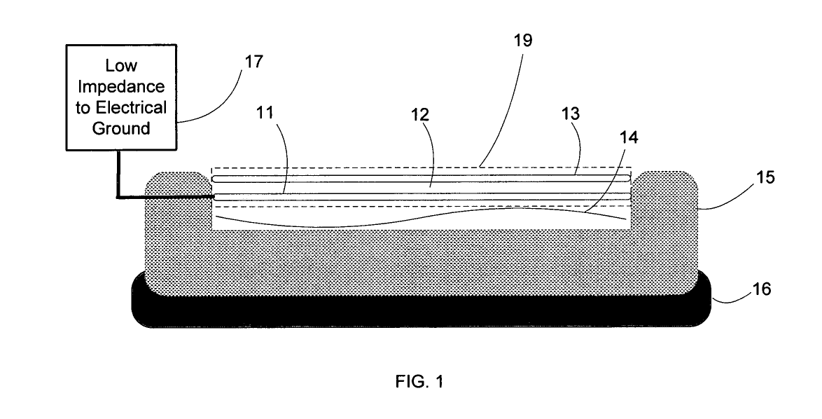

FIG. 1 is a sectional view an occupant detecting apparatus, according to one embodiment.

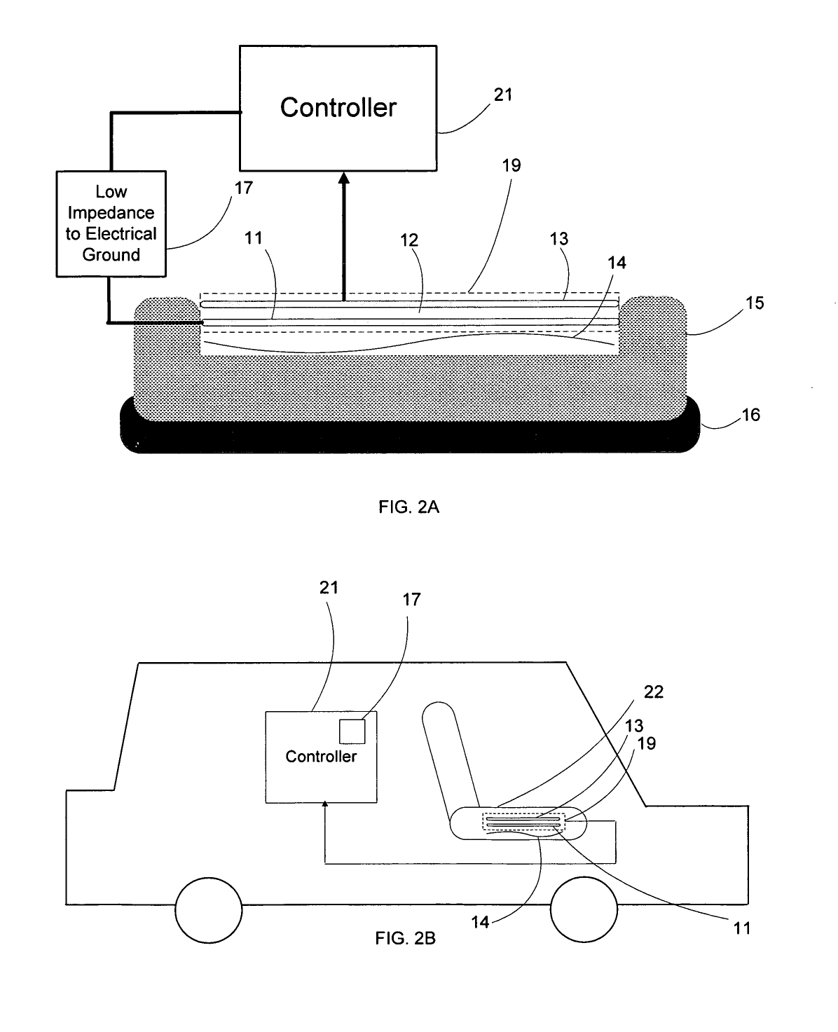

FIG. 2A is a diagram of a vehicle safety system, according to one embodiment.

FIG. 2B is a diagram of a vehicle equipped with an occupant detection system, according to one embodiment.

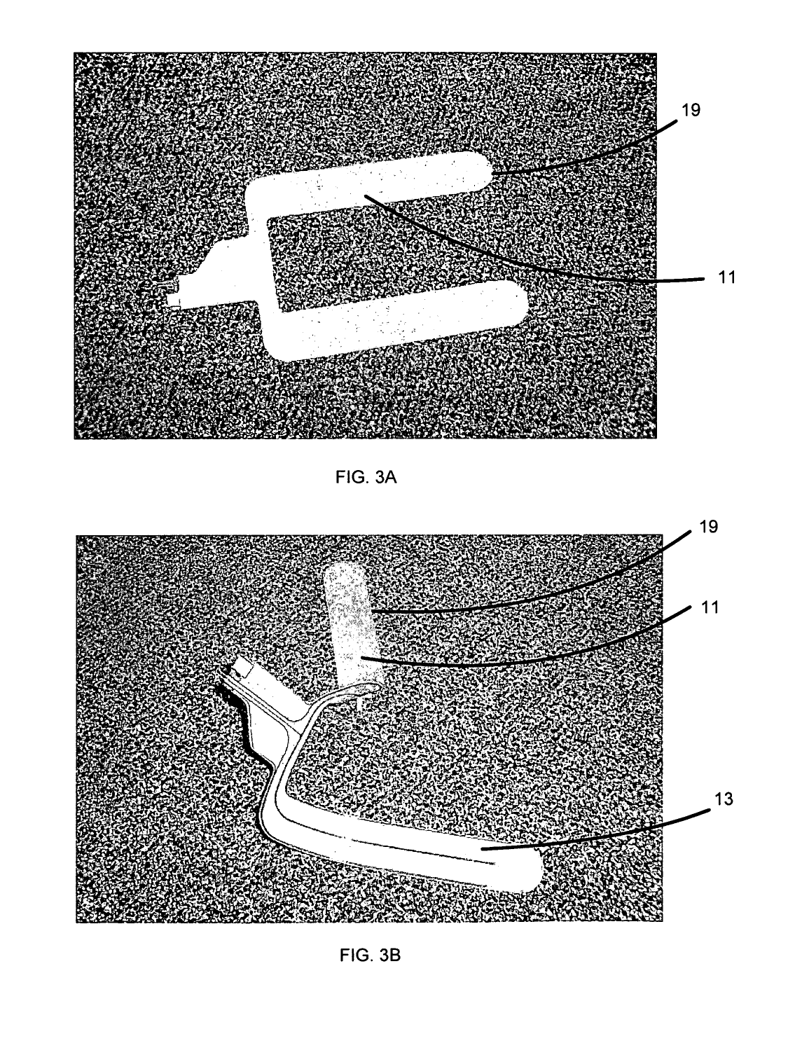

FIG. 3A is a top view of a shielding electrode, according to one embodiment.

FIG. 3B is a side view of a sensor assembly, according to one embodiment.

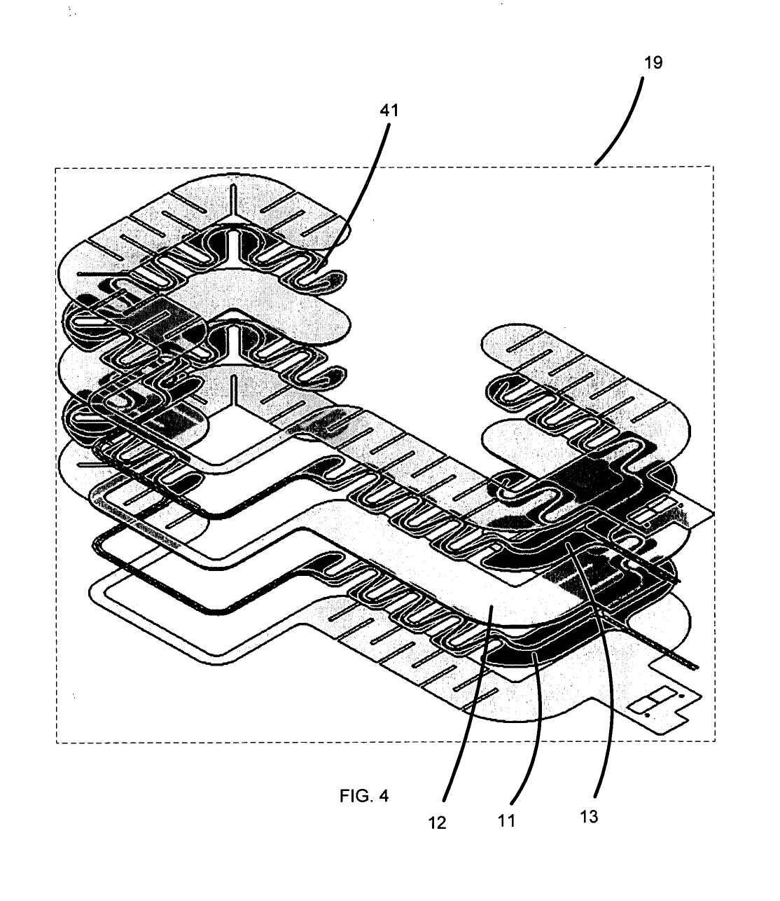

FIG. 4 is an exploded view of a sensor assembly, according to one embodiment.

### DETAILED DESCRIPTION

Embodiments of the present invention will be described below with reference to the accompanying drawings. It should be understood that the following description is intended to describe exemplary embodiments of the invention, and not to limit the invention.

FIG. 1 is a sectional view of an occupant detecting apparatus, according to one embodiment. One embodiment related to FIG. 1 includes a sensor assembly 19 with a sensor 13, and a shielding electrode 11. According to this embodiment, a shielding electrode 11 is coupled, through a low impedance 17, to electrical ground. The presence of the shielding electrode 11 mitigates the susceptibility of the sensor 13 to conductors and other objects having a potential of electrical ground or near electrical ground. The sizes of the sensor 13 and the shielding electrode 11 may vary. In particular, the sensor 13 may be larger than the shielding electrode 11 in any dimension. The sensor 13 may be smaller than the shielding electrode 11 in any dimension. Additionally, the sensor 13 and the shielding electrode 11 may be the same size in any dimension.

Another embodiment related to FIG. 1 includes a sensor assembly 19 with a sensor 13, a shielding electrode 11, and spacer material 12. A seat cushion 15 is attached to a seat frame 16. In this embodiment, a heating element 14, which is a conductor, is located within, or above, the seat cushion 15. As discussed above, the sensor 13 may be susceptible to the presence or absence of an electrical ground. By way of the example, the illustrated embodiment of FIG. 1 includes both a seat frame 16 and a heating element 14. The heating element 14 is a low resistance conductor through which a direct current of several amperes is directed to generate heat. In operation, without a shielding electrode 11, the heating element 14 may appear to be an electrical ground to the sensor 13 without any sort of electrical shielding provided between the sensor 13 and the heating element 14. Further, without a shielding electrode 11 the seat frame 16 may also appear to be an electrical ground to the sensor 13 without any sort of electrical shielding provided between the sensor 13 and the seat frame 16. Without the shielding electrode 11, the heating element 14 or the seat frame 16 could cause inconsistencies in the sensor 13 measurements.

According to the illustrated embodiment of FIG. 1, a shielding electrode 11 is located between the heating element 14 and the sensor 13. In the illustrated embodiment, the shielding electrode 11 is also located between the sensor 13 and the seat frame 16. The shielding electrode 11 is coupled, through a low impedance 17, to electrical ground. In one embodiment, the shielding electrode 11 is coupled, through a low impedance 17, to electrical ground by providing a grounding wire. In other embodiments, the circuit elements of resistors and capacitors may be used to create circuits to couple the shielding electrode 11, through a low impedance 17, to electrical ground. The presence of this shielding electrode 11 in the illustrated embodiment mitigates the susceptibility of the sensor 13 to the ground potential of the heating element 14 and/or the seat frame 16. Further, coupling the shielding electrode 11, through a low impedance 17, to electrical ground eliminates the complexity arising from the need to drive the shielding electrode 11 with the same signal as applied to the sensor 13. The two signals may become different in amplitude or phase depending on sensor 13 sensory conditions. By way of example, in the case of a sensor 13 and shielding electrode 11 designed to detect an object on a vehicle seat, the signal on the shielding electrode 11 may become different from the signal on the sensor 13 because the seat becomes wet. As a result, the circuitry required for the sensor assembly 19 is less complex. Additionally, the illustrated embodiment includes spacer material 12 located between the shielding electrode 11 and the sensor 13.

In some embodiments related to FIG. 1, the sensor 13 may be an electric field sensor. More particularly, the sensor 13 may be a capacitive sensor. In such an embodiment, the spacer material 12 is provided to decrease the offset capacitance of the sensor 13. By way of example, the spacer material 12 can have a thickness in the range of 0.5 mm to 1.5 mm.

In some embodiments related to FIG. 1, the spacer material 12 itself or the attachment of the shielding electrode 11 and the sensor 13 to the spacer material 12 may result in a stiff or inflexible configuration for the sensor assembly 19 that may affect seat comfort. Electrode materials such as flexible circuit films, foils, or sheets, while flexible, have low elongation. Thus, when these types of materials are used for both the sensor 13 and the shielding electrode 11 in a sensor assembly 19, the shear stresses on each surface of the sensor assembly 19 result in an overall stiffness of the assembly 19, even if the spacer material 12 is flexible.

Accordingly, in one embodiment related to FIG. 1, the sensor 13 comprises a flexible material such as conductive sheet, conductive film, or conductive foil. By way of example, FIG. 3B illustrates a sensor 13 constructed from a flexible material in a sensor assembly 19. In such an embodiment, the shielding electrode 11 comprises a material capable of elongation and contraction such as conductive fabric, conductive mesh, and conductive non-woven felt. For example, FIGS. 3A and 3B illustrate a shielding electrode 11 constructed from a copper-coated polyester fabric. The sensor 13 and the shielding electrode 11 are attached to a flexible spacer material 12. Acrylic foam is an example of a flexible spacer material. However, the spacer material 12 need not be a flexible spacer material and may comprise a variety of different materials. The combination of a flexible spacer material 12 with a stretchable electrode material for the shielding electrode 11, in this embodiment, reduces the shear stress on at least one surface of the spacer material 12 which allows the sensor assembly 19 to maintain much of the spacer material's 12 flexibility (as shown in FIG. 3B) reducing the impact of the sensor assembly 19 on seat comfort. Such an embodiment of an assembly 19 allows a more homogeneous feel over seat foam. Additionally, such an assembly 19 is able to more easily conform to the contour of the seat surface.

In another embodiment related to FIG. 1, the sensor 13 comprises a material capable of elongation and contraction such as conductive fabric, conductive mesh, and conductive non-woven felt. In such an embodiment, the shielding electrode 11 comprises a flexible material such as conductive sheet, conductive film, or conductive foil. The sensor 13 and the shielding electrode 11 are attached to a flexible spacer material 12. Acrylic foam is an example of a flexible spacer material. The combination of a flexible spacer material 12 with a stretchable electrode material for the sensor 13, in this embodiment, reduces the shear stress on at least one surface of the spacer material 12 which allows the sensor assembly 19 to maintain much of the spacer material's 12 flexibility reducing the impact of the sensor assembly 19 on seat comfort. Such an embodiment of an assembly 19 allows a more homogeneous feel over seat foam. Additionally, such an assembly 19 is able to more easily conform to the contour of the seat surface.

In another embodiment related to FIG. 1, the sensor 13 comprises a flexible material such as a flexible circuit material comprising etched or deposited conductive material applied to a dielectric substrate. By way of example, FIG. 3B illustrates a sensor 13 constructed from a flexible material in a sensor assembly 19. In such an embodiment, the shielding electrode 11 comprises a material capable of elongation and contraction such as conductive fabric, conductive mesh, and conductive non-woven felt. For example, FIGS. 3A and 3B illustrate a shielding electrode 11 constructed from a copper-coated polyester fabric. The sensor 13 and the shielding electrode 11 are attached to a flexible spacer material 12. Acrylic foam is an example of a flexible spacer material. The combination of a flexible spacer material 12 with a stretchable electrode material for the shielding electrode 11, in this embodiment, reduces the shear stress on at least one surface of the spacer material 12 which allows the sensor assembly 19 to maintain much of the spacer material's 12 flexibility (as shown in FIG. 3B) reducing the impact of the sensor assembly 19 on seat comfort. Such an embodiment of an assembly 19 allows a more homogeneous feel over seat foam. Additionally, such an assembly 19 is able to more easily conform to the contour of the seat surface.

In another embodiment related to FIG. 1, the sensor 13 comprises a material capable of elongation and contraction such as conductive fabric, conductive mesh, and conductive non-woven felt. In such an embodiment, the shielding electrode 11 comprises a flexible material such as a flexible circuit material comprising etched or deposited conductive material applied to a dielectric substrate. The sensor 13 and the shielding electrode 11 are attached to a flexible spacer material 12. Acrylic foam is an example of a flexible spacer material. The combination of a flexible spacer material 12 with a stretchable electrode material for the sensor 13, in this embodiment, reduces the shear stress on at least one surface of the spacer material 12 which allows the sensor assembly 19 to maintain much of the spacer material's 12 flexibility reducing the impact of the sensor assembly 19 on seat comfort. Such an embodiment of an assembly 19 allows a more homogeneous feel over seat foam. Additionally, such an assembly 19 is able to more easily conform to the contour of the seat surface.

In another embodiment related to FIG. 1, the sensor 13 comprises a material capable of elongation and contraction such as conductive fabric, conductive mesh, and conductive non-woven felt. In such an embodiment, the shielding electrode 11 also comprises a material capable of elongation and contraction such as conductive fabric, conductive mesh, and conductive non-woven felt. The sensor 13 and the shielding electrode 11 are attached to a flexible spacer material 12. Acrylic foam is an example of a flexible spacer material. The combination of a flexible spacer material 12 with a stretchable electrode material for the sensor 13 and the shielding electrode 11, in this embodiment, reduces the shear stress on both surfaces of the spacer material 12 which allows the sensor assembly 19 to maintain much of the spacer material's 12 flexibility reducing the impact of the sensor assembly 19 on seat comfort. Such an embodiment of an assembly 19 allows a more homogeneous feel over seat foam. Additionally, such an assembly 19 is able to more easily conform to the contour of the seat surface.

In some embodiments related to FIG. 1, the spacer material 12 itself or the attachment of the shielding electrode 11 and the sensor 13 to the spacer material 12 may result in a stiff or inflexible configuration for the sensor assembly 19 that may affect seat comfort, as previously disclosed.

Accordingly, in one embodiment related to FIG. 1, the sensor 13 comprises a material having at least one slot 41, where a slot 41 is a void section of the material. By way of example, FIG. 4 illustrates a sensor 13 comprising a flexible material having a plurality of slots 41. As an alternative to a slot 41, the sensor 13 may include any suitable void section of material. In some embodiments, the material of the sensor 13 is a flexible material such as conductive sheet, conductive film, or conductive foil. In other embodiments, the material of the sensor 13 is a flexible circuit material comprising etched or deposited conductive material applied to a dielectric substrate. In yet other embodiments, the material of the sensor 13 is a material that elongates and contracts such as conductive fabric, conductive mesh, or conductive non-woven felt. The shielding electrode 11 may comprise any one of variety of different materials. In some embodiments, the shielding electrode 11 may comprise a flexible material such as conductive sheet, conductive film, or conductive foil. In other embodiments, the shielding electrode 11 may comprise a flexible material such as a flexible circuit material comprising etched or deposited conductive material applied to a dielectric substrate. In yet other embodiments, the shielding electrode 11 may comprise a material capable of elongation and contraction such as conductive fabric, conductive mesh, and conductive non-woven felt. In some embodiments, the sensor 13 and the shielding electrode 11 are attached to a flexible spacer material 12. Acrylic foam is an example of a flexible spacer material. In other embodiments, the spacer material 12 may comprise a material having at least one slot 41, where a slot is a void section of the material, as illustrated in FIG. 4. As an alternative to a slot 41, the spacer material 12 may include any suitable void section of material. The combination of a flexible spacer material 12 with the sensor 13 comprising a material having at least one slot, in this embodiment, reduces the shear stress on at least one surface of the spacer material 12 which allows the sensor assembly 19 to maintain much of the spacer material's 12 flexibility reducing the impact of the sensor assembly 19 on seat comfort. Such an embodiment of an assembly 19 allows a more homogeneous feel over seat foam. Additionally, such an assembly 19 is able to more easily conform to the contour of the seat surface.

In another embodiment related to FIG. 1, the shielding electrode 11 comprises a material having at least one slot 41, where a slot 41 is a void section of the material. By way of example, FIG. 4 illustrates a shielding electrode 11 comprising a flexible material having a plurality of slots 41. As an alternative to a slot 41, the shielding electrode 11 may include any suitable void section of material. In some embodiments, the material of the shielding electrode 11 is a flexible material such as conductive sheet, conductive film, or conductive foil. In other embodiments, the material of the shielding electrode 11 is a flexible circuit material comprising etched or deposited conductive material applied to a dielectric substrate. In yet other embodiments, the material of the shielding electrode 11 is a material that elongates and contracts such as conductive fabric, conductive mesh, or conductive non-woven felt. The sensor 13 may comprise any one of a variety of different materials. In some embodiments, the sensor 13 may comprise a flexible material such as conductive sheet, conductive film, or conductive foil. In other embodiments, the sensor 13 may comprise a flexible material such as a flexible circuit material comprising etched or deposited conductive material applied to a dielectric substrate. In yet other embodiments, the sensor 13 may comprise a material capable of elongation and contraction such as conductive fabric, conductive mesh, and conductive non-woven felt. The sensor 13 and the shielding electrode 11 are attached to a flexible spacer material 12. Acrylic foam is an example of a flexible spacer material. The combination of a flexible spacer material 12 with the shielding electrode 11 comprising a material having at least one slot, in this embodiment, reduces the shear stress on at least one surface of the spacer material 12 which allows the sensor assembly 19 to maintain much of the spacer material's 12 flexibility reducing the impact of the sensor assembly 19 on seat comfort. Such an embodiment of an assembly 19 allows a more homogeneous feel over seat foam. Additionally, such an assembly 19 is able to more easily conform to the contour of the seat surface.

In yet other embodiments related to FIG. 1, the sensor 13 comprises a material having at least one slot 41, where a slot 41 is a void section of the material. By way of example, FIG. 4 illustrates a sensor 13 comprising a flexible material having a plurality of slots 41. In some embodiments, the material of the sensor 13 is a flexible material such as conductive sheet, conductive film, or conductive foil. In other embodiments, the material of the sensor 13 is a flexible circuit material comprising etched or deposited conductive material applied to a dielectric substrate. In yet other embodiments, the material of the sensor 13 is a material that elongates and contracts such as conductive fabric, conductive mesh, or conductive non-woven felt. Additionally, the shielding electrode 11 comprises a material having at least one slot 41, where a slot 41 is a void section of the material. By way of example, FIG. 4 illustrates a shielding electrode 11 comprising a flexible material having a plurality of slots 41. In some embodiments, the material of the shielding electrode 11 is a flexible material such as conductive sheet, conductive film, or conductive foil. In other embodiments, the material of the shielding electrode 11 is a flexible circuit material comprising etched or deposited conductive material applied to a dielectric substrate. In yet other embodiments, the material of the shielding electrode 11 is a material that elongates and contracts such as conductive fabric, conductive mesh, or conductive non-woven felt. The sensor 13 and the shielding electrode 11 are attached to a flexible spacer material 12. Acrylic foam is an example of a flexible spacer material. The combination of a flexible spacer material 12 with the sensor 13 and shielding electrode 11 comprising a material having at least one slot, in this embodiment, reduces the shear stress on at least one surface of the spacer material 12 which allows the sensor assembly 19 to maintain much of the spacer material's 12 flexibility reducing the impact of the sensor assembly 19 on seat comfort. Such an embodiment of an assembly 19 allows a more homogeneous feel over seat foam. Additionally, such an assembly 19 is able to more easily conform to the contour of the seat surface.

Referring now to FIG. 2A. FIG. 2A is a diagram of a vehicle safety system, according to one embodiment. This embodiment includes an sensor assembly 19 with an electric field sensor 13, a shielding electrode 11, and spacer material 12. A seat cushion 15 is attached to a seat frame 16. A heating element 14, which is a conductor, is located within, or above, the seat cushion 15. The shielding electrode 11 operates as disclosed in the discussion of FIG. 1 above. Additionally, the sensor assembly 19 may be constructed as disclosed above. A controller 21 is connected to the electric field sensor 13 for controlling the vehicle safety system. In addition, in an embodiment of an occupant detection system related to FIG. 2A, the controller 21 is connected to the electric field sensor 13 for classifying the occupant. In such an embodiment, the occupant classification result may be used to decide whether to deploy safety system actuators such as airbags or belt pretensioners. In the illustrated embodiment of FIG. 2A, the controller 21 is also coupled, through a low impedance 17, to electrical ground. In some embodiments, the circuitry for the low impedance 17 is housed in the controller 21. In some embodiments, the provided electric field sensor 13 is for detecting an object in a vehicle seat, such as a passenger. In such an embodiment, the presence of a passenger is sensed by the electric field sensor 13 and the controller 21, which is connected to the electric field sensor 13, controls the vehicle safety system based on the presence of the passenger. In some embodiments, safety sub-systems such as an airbag sub-system may be controlled by the vehicle safety system.

Referring now to FIG. 2B. FIG. 2B is a diagram of a vehicle equipped with an occupant detection system. In such an embodiment a sensor assembly 19 is located in a vehicle seat 22. The controller 21 is connected to the electric field sensor 13 for classification of an occupant. The occupant classification result may be used to decide whether to deploy safety system actuators such as airbags or belt pretensioners. Additionally, in some embodiments, both the shielding electrode 11 and the controller 21 are coupled, through a low impedance 17 located within the controller 21, to electrical ground.

The various embodiments described above may be incorporated into a vehicle seat such as shown in U.S. Pat. No. 6,703,845 (incorporated by reference herein), for example. Additionally, the sensors described above may operate and may be constructed such as described in U.S. Pat. No. 6,703,845.

Given the disclosure of the present invention, one versed in the art would appreciate that there may be other embodiments and modifications within the scope and spirit of the invention. Accordingly, all modifications attainable by one versed in the art from the present disclosure within the scope and spirit of the present invention are to be included as further embodiments of the present invention.

What is claimed is:

1. An occupant detection apparatus, comprising:
a sensor; and
a shielding electrode located between the sensor and a conductor, wherein the shielding electrode is coupled, through a low impedance, to electrical ground.

2. The occupant detection apparatus of claim 1, further comprising a spacer located between the sensor and the shielding electrode.

3. The occupant detection apparatus of claim 2, wherein the spacer is a flexible material.

4. The occupant detection apparatus of claim 3, wherein the spacer is acrylic foam.

5. The occupant detection apparatus of claim 1, wherein the conductor is a heating element.

6. The occupant detection apparatus of claim 1, wherein the sensor comprises a material that elongates and contracts.

7. The occupant detection apparatus of claim 6, wherein the material comprises at least one of a conductive fabric, a conductive mesh, and a conductive non-woven felt.

8. The occupant detection apparatus of claim 1, wherein the sensor comprises a flexible material.

9. The occupant detection apparatus of claim 8, wherein the flexible material comprises at least one of a conductive sheet, a conductive film, and a conductive foil.

10. The occupant detection apparatus of claim 8, wherein the flexible material is a flexible circuit material comprising etched or deposited conductive material applied to a dielectric substrate.

11. The occupant detection apparatus of claim 1, wherein the sensor is an electric field sensor.

12. The occupant detection apparatus of claim 11, wherein the electric field sensor is a capacitive sensor.

13. The occupant detection apparatus of claim 1, wherein the shielding electrode comprises a material that elongates and contracts.

14. The occupant detection apparatus of claim 13, wherein the material comprises at least one of a conductive fabric, a conductive mesh, and a conductive non-woven felt.

15. The occupant detection apparatus of claim 14, wherein the shielding electrode comprises a copper-coated polyester fabric.

16. The occupant detection apparatus of claim 1, wherein the shielding electrode comprises a flexible material.

17. The occupant detection apparatus of claim 16, wherein the flexible material comprises at least one of a conductive sheet, a conductive film, and a conductive foil.

18. The occupant detection apparatus of claim 16, where the material is a flexible circuit material comprising etched or deposited conductive material applied to a dielectric substrate.

19. The occupant detection apparatus of claim 1, wherein the sensor comprises a material having at least one slot, wherein a slot is a void section of material.

20. The occupant detection apparatus of claim 19, wherein the material is a flexible material.

21. The occupant detection apparatus of claim 20, wherein the flexible material comprises at least one of a conductive sheet, a conductive film, and a conductive foil.

22. The occupant detection apparatus of claim 20, wherein the flexible material is a flexible circuit material comprising etched or deposited conductive material applied to a dielectric substrate.

23. The occupant detection apparatus of claim 1, wherein the shielding electrode comprises a material having at least one slot, wherein a slot is a void section of material.

24. The occupant detection apparatus of claim 23, wherein the material is a flexible material.

25. The occupant detection apparatus of claim 24, wherein the flexible material comprises at least one of a conductive sheet, a conductive film, and a conductive foil.

26. The occupant detection apparatus of claim 24, wherein the material is a flexible circuit material comprising etched or deposited conductive material applied to a dielectric substrate.

27. A sensing system for a heated seat, comprising:
a heating element;
a sensor;
a shielding electrode located between the sensor and the heating element, wherein the shielding electrode is coupled, through a low impedance, to electrical ground.

28. An occupant classification system within a vehicle seat, comprising:
a heating element;
an electric field sensor;
a shielding electrode located between the electric field sensor and the heating element, wherein the shielding electrode is coupled, through a low impedance, to electrical ground; and
a controller connected to the electric field sensor for classification of an occupant.

29. A vehicle safety system, comprising:
a heating element;
an electric field sensor;
a shielding electrode located between the electric field sensor and the heating element, wherein the shielding electrode is coupled, through a low impedance, to electrical ground; and
a controller connected to the electric field sensor for controlling the vehicle safety system.
